(19) United States
(12) Patent Application Publication
(10) Pub. No.: US 2025/0359434 A1
(43) Pub. Date: Nov. 20, 2025

(54) DISPLAY DEVICE AND FOLDABLE DISPLAY DEVICE

(71) Applicant: Samsung Display Co., LTD., Yongin-si (KR)

(72) Inventors: Hyoung Sik KIM, Yongin-si (KR); Do Keun SONG, Yongin-si (KR); Yeong Woo KWON, Yongin-si (KR); Jong Hoon CHOI, Yongin-si (KR)

(21) Appl. No.: 18/987,321

(22) Filed: Dec. 19, 2024

(30) Foreign Application Priority Data
May 14, 2024 (KR) 10-2024-0062992

(51) Int. Cl. H10K 59/122; H10K 102/00

(52) U.S. Cl. CPC H10K 59/122; H10K 2102/311

(57) ABSTRACT

A display device includes a substrate including first, second and third emission areas spaced apart from each other; a first bridge bank including a first bank on the substrate and a second bank on the first bank, between the first and second emission areas aligned in a first direction; and a second bridge bank including a first bank on the substrate and a second bank on the first bank, between the second and third emission areas aligned in a second direction. The first bridge bank extends in the first direction, the second bridge bank extends in the second direction, a width of the first bank of the first bridge bank is less than a width of the second bank of the first bridge bank, and a width of the first bank of the second bridge bank is less than a width of the second bank of the second bridge bank.

This application claims priority to Korean Patent Application No. 10-2024-0062992, filed on May 14, 2024, and all the benefits accruing therefrom under 35 U.S.C. § 119, the content of which in its entirety is herein incorporated by reference.

### BACKGROUND

### 1. Field

The disclosure relates to a display device and a foldable display device.

### 2. Description of the Related Art

With the advance of information-oriented society, more and more demands are placed on display devices for displaying images in various ways. For example, display devices are employed in various electronic devices such as smartphones, digital cameras, laptop computers, navigation devices, and smart televisions. The display device may be a flat panel display device such as a liquid crystal display device, a field emission display device and an organic light-emitting display device. Among the flat panel display devices, in the light-emitting display device, since each of pixels of a display panel includes a light-emitting element capable of emitting light by itself, an image may be displayed without a backlight unit providing light to the display panel.

Recently, the display device is employed in a glass-type device for providing virtual reality and augmented reality. In order to be employed in the glass-type device, the display device needs to be implemented in a substantially small size of 2 inches or less, or needs to have a high pixel pitch to be implemented with high resolution. For example, the display device may have a high pixel pitch of 400 pixels per inch (PPI) or more.

### SUMMARY

Features of the disclosure provide a display device and a foldable display device capable of forming separated light-emitting elements in relatively small emission areas without a mask process.

Features of the disclosure also provide a display device and a foldable display device in which a bank structure is not damaged even when folded.

However, features of the disclosure are not restricted to those set forth herein. The above and other features of the disclosure will become more apparent to one of ordinary skill in the art to which the disclosure pertains by referencing the detailed description of the disclosure given below.

In an embodiment of the disclosure, a display device includes a substrate in which a first emission area, a second emission area, and a third emission area spaced apart from each other are defined; a first bridge bank including a first bank on the substrate and a second bank on the first bank, between the first emission area and the second emission area; and a second bridge bank including a first bank on the substrate and a second bank on the first bank, between the second emission area and the third emission area. The first emission area and the second emission area are aligned in a first direction, the first bridge bank mainly extends in the first direction, and has a zigzag shape or a wave shape, the second emission area and the third emission area are aligned in a second direction crossing the first direction, the second bridge bank extends in the second direction, a width of the first bank of the first bridge bank is less than a width of the second bank of the first bridge bank, and a width of the first bank of the second bridge bank is less than a width of the second bank of the second bridge bank.

In an embodiment, in the second direction, a width of the first bridge bank may be less than a width of the first emission area and a width of the second emission area.

In an embodiment, the width of the first bridge bank may be 1 micrometer (μm) to 10 μm.

In an embodiment, in the first direction, a width of the second bridge bank may be less than a width of the second emission area and a width of the third emission area.

In an embodiment, the width of the second bridge bank may be 1 μm to 10 μm.

In an embodiment, the second bridge bank may have a straight line shape extending in the second direction.

In an embodiment, the second bridge bank may mainly extend in the second direction, and may have a zigzag shape or a wave shape.

In an embodiment, the display device may be folded in the first direction.

In an embodiment, the display device may further include a first pixel electrode on the substrate in the first emission area; a second pixel electrode on the substrate in the second emission area; a pixel defining layer defining the first emission area and the second emission area on the substrate; a first light-emitting layer on the first pixel electrode and a first common electrode on the first light-emitting layer; and a second light-emitting layer on the second pixel electrode and a second common electrode on the second light-emitting layer. The first common electrode and the second common electrode may be spaced apart from each other.

In an embodiment, the first bank of the first bridge bank may contact one end of the first common electrode and one end of the second common electrode.

In an embodiment, the display device may further include a first inorganic layer on the first common electrode and the first bridge bank.

In an embodiment, the first inorganic layer may be spaced apart from a top surface of the second bank of the first bridge bank.

In an embodiment, the first inorganic layer may contact the pixel defining layer.

In an embodiment, the display device may further include a second inorganic layer on the second common electrode and the first bridge bank. The first inorganic layer and the second inorganic layer may be spaced apart from each other.

In an embodiment, the display device may further include a residual pattern disposed between the first pixel electrode and the pixel defining layer.

In an embodiment of the disclosure, a display device includes a substrate in which a plurality of emission areas are defined; a first bridge bank extending in a first direction, and including a first bank on the substrate and a second bank on the first bank; and a second bridge bank extending in a second direction crossing the first direction, and including a first bank on the substrate and a second bank on the first bank. The plurality of emission areas is aligned in the first direction and the second direction, the first bridge bank is disposed between emission areas next to each other and aligned in the first direction among the plurality of plurality of emission areas, the second bridge bank is disposed between emission areas next to each other and aligned in the second direction among the plurality of plurality of emission areas, a width of the first bank of the first bridge bank is less than a width of the second bank of the first bridge bank, and a width of the first bank of the second bridge bank is less than a width of the second bank of the second bridge bank.

In an embodiment, a shape of the first bridge bank manly extending in the first direction and a shape of the second bridge bank extending in the second direction may be different from each other.

In an embodiment, the first bridge bank extending in the first direction may have a zigzag shape or a wave shape, and the second bridge bank extending in the second direction may have a straight line shape.

In an embodiment, each of the plurality of emission areas may be disposed at a grid point of grid patterns which intersect in the first direction and the second direction.

In an embodiment of the disclosure, a display device includes a substrate in which a first emission area, a second emission area, a third emission area, and a fourth emission area spaced apart from each other are defined; a first bridge bank mainly extending in a first direction, and including a first bank on the substrate and a second bank on the first bank; and a second bridge bank extending in a second direction crossing the first direction, and including a first bank on the substrate and a second bank on the first bank. The first emission area is aligned with the second emission area in the first direction, and is aligned with the fourth emission area in the second direction, the third emission area is aligned with the fourth emission area in the first direction, and is aligned with the second emission area in the second direction, the first bridge bank has a zigzag shape or wave shape, the second bridge bank has a straight line shape, a width of the first bank of the first bridge bank is less than a width of the second bank of the first bridge bank, and a width of the first bank of the second bridge bank is less than a width of the second bank of the second bridge bank.

In an embodiment of the disclosure, a foldable display device includes a display panel including a folding area and a non-folding area disposed around the folding area. The display panel includes a substrate in which a first emission area, a second emission area, and a third emission area spaced apart from each other in the folding area are defined; a first bridge bank including a first bank on the substrate and a second bank on the first bank, between the first emission area and the second emission area; and a second bridge bank including a first bank on the substrate and a second bank on the first bank, between the second emission area and the third emission area. The first emission area and the second emission area are aligned in a first direction, the first bridge bank mainly extends in the first direction, and has a zigzag shape or wave shape, the second emission area and the third emission area are aligned in a second direction crossing the first direction, the second bridge bank extends in the second direction, a width of the first bank of the first bridge bank is less than a width of the second bank of the first bridge bank, and a width of the first bank of the second bridge bank is less than a width of the second bank of the second bridge bank.

In accordance with a display device in an embodiment, a bank structure is formed in a bridge shape in a folding area, thereby reducing folding stress.

However, effects in the embodiments of the disclosure are not limited to those exemplified above and various other effects are incorporated herein.

### BRIEF DESCRIPTION OF THE DRAWINGS

The above and other advantages and features of the disclosure will become more apparent by describing in detail embodiments thereof with reference to the attached drawings, in which:

FIG. 1 is a perspective view illustrating an embodiment of a foldable display device in an unfolded state;

FIG. 2 is a perspective view illustrating an embodiment of the foldable display device in a folded state;

FIG. 3 is a cross-sectional view of an embodiment of a display device taken along line I-I′ of FIG. 1;

FIG. 4 is a cross-sectional view of an embodiment of the display device in a folded state;

FIG. 5 is a plan view showing an embodiment of an arrangement of emission areas and a first bank structure in non-folding areas of the display device;

FIG. 6 is a cross-sectional view of an embodiment of the display device taken along line II-II′ of FIG. 5;

FIG. 7 is an enlarged view showing area A1 of FIG. 6;

FIG. 8 is a plan view showing an embodiment of an arrangement of emission areas and a second bank structure in a folding area of the display device;

FIGS. 9A to 9C are cross-sectional views of an embodiment of the display device taken along lines III-III′, IV-IV′, and V-V′ of FIG. 8, respectively;

FIGS. 10 and 11 are plan views showing an embodiment of an arrangement of the emission areas and a second bank structure in the folding area of the display device in an embodiment, respectively; and

FIG. 12 is a plan view showing an embodiment of an arrangement of the emission areas and a first bank structure in the non-folding areas of the display device.

FIG. 13 is a block diagram of an electronic device according to one embodiment of the present disclosure.

FIG. 14 is a schematic diagram of an electronic device according to various embodiments of the present disclosure.

### DETAILED DESCRIPTION

Embodiments of the disclosure now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it may be directly on the other element or intervening elements may be therebetween.

In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the drawing figures. It will be understood that relative terms are intended to encompass different orientations of the device in addition to the orientation depicted in the drawing figures. For example, if the device in one of the drawing figures is turned over, elements described as being on the “lower” side of other elements would then be oriented on “upper” sides of the other elements. The term “lower,” may therefore, encompasses both an orientation of “lower” and “upper,” depending on the particular orientation of the figure. Similarly, if the device in one of the drawing figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” may mean within one or more standard deviations, or within ±30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the drawing figures are schematic in nature and their shapes are not intended to illustrate the precise shape of a region and are not intended to limit the scope of the claims.

Hereinafter, embodiments will be described in detail with reference to the accompanying drawings.

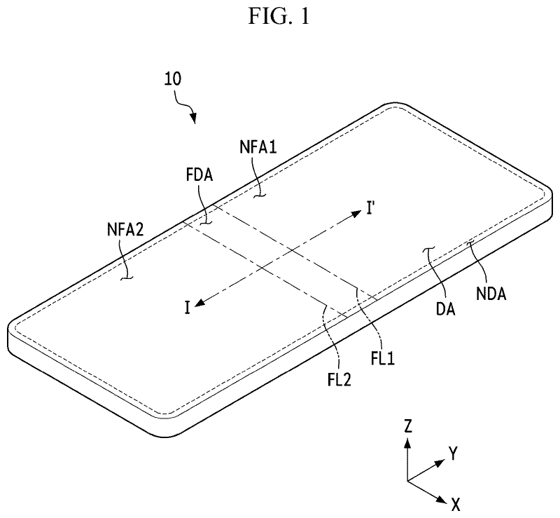

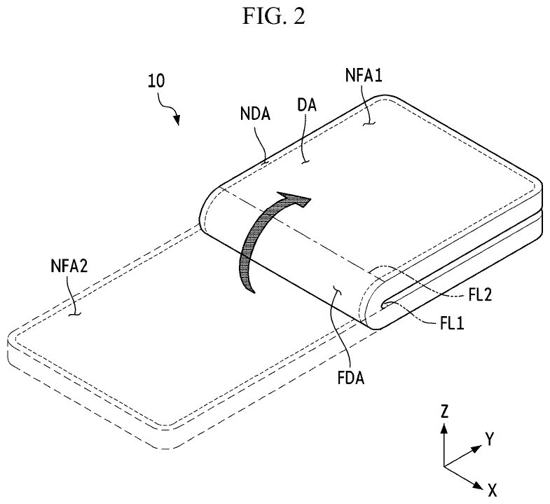

FIGS. 1 and 2 are perspective views illustrating an embodiment of a foldable display device 10. FIG. 1 is a perspective view illustrating an embodiment of the foldable display device 10 in an unfolded state. FIG. 2 is a perspective view illustrating an embodiment of the foldable display device 10 in a folded state.

In FIGS. 1 and 2, a first direction (X-axis direction) may be a direction parallel to one side of the display device 10 in a plan view and may be, for example, a widthwise direction of the display device 10, for example. A second direction (Y-axis direction) may be a direction parallel to a perpendicular side in contact with one side of the display device 10 in a plan view and may be, for example, a longitudinal direction of the display device 10. A third direction (Z-axis direction) may be a thickness direction of the display device 10.

The display device 10 may have a quadrangular shape, e.g., rectangular or square shape in a plan view. The display device 10 may have a quadrangular shape, e.g., rectangular shape with right-angled or rounded corners in a plan view. The display device 10 may include two short sides arranged in the first direction (X-axis direction) and two long sides arranged in the second direction (Y-axis direction) in a plan view.

The display device 10 includes a display area DA and a non-display area NDA. In plan view, the shape of the display area DA may correspond to the shape of the display device 10. In an embodiment, when the display device 10 has a quadrilateral shape, e.g., rectangular shape in a plan view, the display area DA may also have a quadrilateral shape, e.g., rectangular shape, for example.

The display area DA may be an area including a plurality of pixels to display an image. The plurality of pixels may be arranged in a matrix. The plurality of pixels may have a quadrilateral shape, e.g., rectangular, rhombic, square, or octagonal shape in a plan view, without being limited thereto. In an embodiment, the plurality of pixels may have a quadrilateral shape other than a quadrilateral shape, e.g., rectangular, rhombic, or square shape, a polygonal shape other than the quadrilateral shape, a circular shape, or an elliptical shape, for example.

The non-display area NDA may be an area that does not include pixels and does not display an image. The non-display area NDA may be disposed around the display area DA. The non-display area NDA may be disposed to surround the display area DA as shown in FIGS. 1 and 2, but is not limited thereto. The display area DA may be partially surrounded by the non-display area NDA.

The display device 10 may be a foldable display device capable of maintaining both a folded state and an unfolded state. As shown in FIG. 2, the display device 10 may be folded in an in-folding manner in which the display area DA is disposed on the inside. When the display device 10 is folded in the in-folding manner, front surfaces of the display device 10 may face each other. In an alternative embodiment, the display device 10 may be folded in an out-folding manner in which the display area DA is disposed on the outside. When the display device 10 is folded in the out-folding manner, rear surfaces of the display device 10 may face each other.

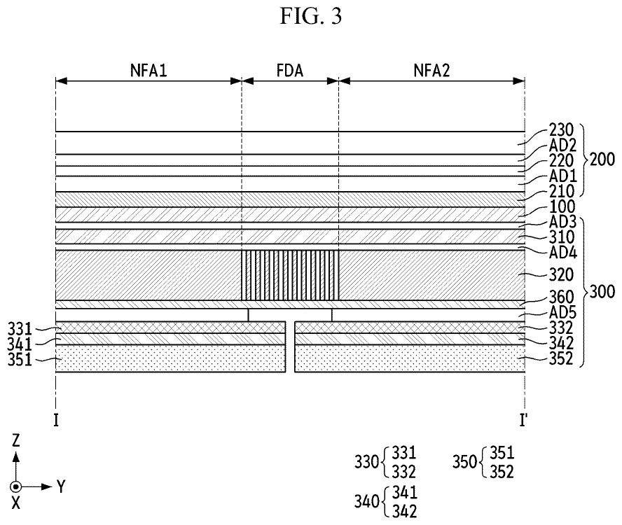

A display panel 100 (refer to FIG. 3) of the display device 10 may include a folding area FDA, a first non-folding area NFA1, and a second non-folding area NFA2. The folding area FDA may be an area in which the display device 10 is folded or bent, and the first non-folding area NFA1, and the second non-folding area NFA2 may be areas in which the display device 10 is not folded or bent. The first non-folding area NFA1 and the second non-folding area NFA2 may be disposed around the folding area FDA.

The first non-folding area NFA1 may be disposed on one side (e.g., an upper side) of the folding area FDA. The second non-folding area NFA2 may be disposed on an opposite side (e.g., a lower side) of the folding area FDA. The folding area FDA, which is defined by a first folding line FL1 and a second folding line FL2, may be a curved area with a predetermined curvature. The first folding line FL1 may be the boundary between the folding area FDA and the first non-folding area NFA1, and the second folding line FL2 may be the boundary between the folding area FDA and the second non-folding area NFA2.

The first folding line FL1 and the second folding line FL2 may extend in the first direction (X-axis direction) as shown in FIGS. 1 and 2. In this case, the display device 10 may be folded in the second direction (Y-axis direction). Accordingly, the length of the display device 10 in the second direction (Y-axis direction) may be reduced to approximately half, so that a user may conveniently carry the display device 10. Without being limited to FIGS. 1 and 2, the first folding line FL1 and the second folding line FL2 may extend in the second direction (Y-axis direction), and the display device 10 may also be folded in the first direction (X-axis direction). In this case, the length of the display device 10 in the first direction (X-axis direction) may be reduced to approximately half.

When the first folding line FL1 and the second folding line FL2 extend in the first direction (X-axis direction) as shown in FIGS. 1 and 2, the length of the folding area FDA in the second direction (Y-axis direction) may be less than the length of the folding area FDA in the first direction (X-axis direction). Further, the length of the first non-folding area NFA1 in the second direction (Y-axis direction) may be greater than the length of the first non-folding area NFA1 in the first direction (X-axis direction). The length of the second non-folding area NFA2 in the second direction (Y-axis direction) may be greater than the length of the second non-folding area NFA2 in the first direction (X-axis direction).

Each of the display area DA and the non-display area NDA may overlap at least one of the folding area FDA, the first non-folding area NFA1, or the second non-folding area NFA2. FIGS. 1 and 2 illustrate that each of the display area DA and the non-display area NDA overlaps the folding area FDA, the first non-folding area NFA1, and the second non-folding area NFA2.

FIG. 3 is a cross-sectional view of an embodiment of the display device 10 taken along line I-I′ of FIG. 1.

Referring to FIG. 3, the display device 10 may include a display panel 100, a front laminated structure 200 on the front side of the display panel 100, and a rear laminated structure 300 on the rear side of the display panel 100. Here, the front side of the display panel 100 refers to a side on which the display panel 100 displays a screen, and the rear side thereof refers to the opposite side of the front side. One surface of the display panel 100 is disposed on the front side, and an opposite surface of the display panel 100 is disposed on the rear side.

The front laminated structure 200 may include a polarizing film 210, a window 220, and a protective film 230. The rear laminated structure 300 may include a panel lower member 310, a light-blocking member 320, a digitizer layer 330, a shielding member 340, a heat dissipation member 350, and a buffer member 360.

In addition, the front laminated structure 200 may further include a first adhesive member AD1 disposed between the polarizing film 210 and the window 220, and a second adhesive member AD2 disposed between the window 220 and the protective film 230. The rear laminated structure 300 may further include a third adhesive member AD3 disposed between the display panel 100 and the panel lower member 310, a fourth adhesive member AD4 disposed between the panel lower member 310 and the light-blocking member 320, and a fifth adhesive member AD5 disposed between the digitizer layer 330 and the buffer member 360.

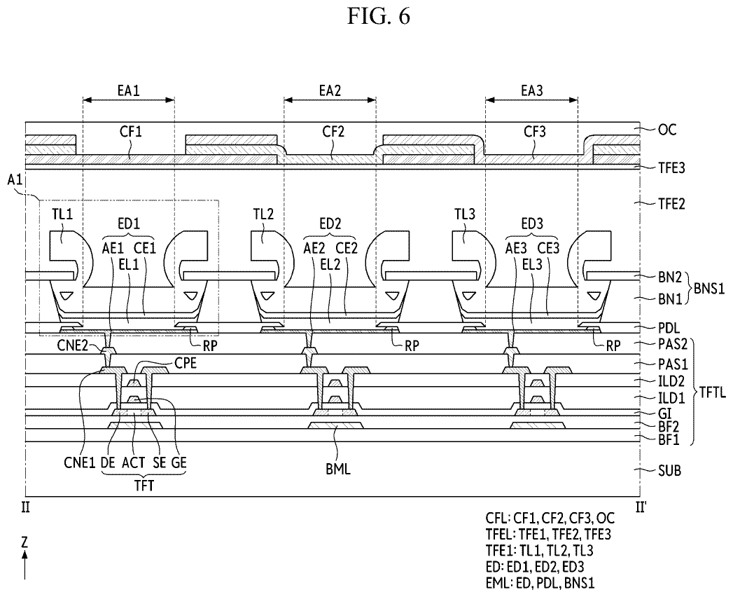

A panel for displaying an image may be an organic light-emitting display panel using an organic light-emitting diode, a quantum dot light-emitting display panel including a quantum dot light-emitting layer, an inorganic light-emitting display panel including an inorganic semiconductor, or a micro light-emitting display panel using a micro light-emitting diode (“LED”). In the following description, it is assumed that the display panel 100 is an organic light-emitting display panel, but the disclosure is not limited thereto. The display panel 100 will be described in detail later with reference to FIG. 6.

The polarizing film 210 may be disposed on the front surface of the display panel 100. The polarizing film 210 may be attached to the front surface of the display panel 100.

The window 220 may be disposed on the front surface of the polarizing film 210. The window 220 may be adhered to the front surface of the polarizing film 210 by the first adhesive member AD1. The window 220 may include or consist of a transparent material and may contain glass or plastic, for example. In an embodiment, the window 220 may be an ultra thin glass (“UTG”) with a thickness of 0.1 millimeter (mm) or less or a transparent polyimide film, for example, but is not limited thereto.

The protective film 230 may be disposed on the front surface of the window 220. The protective film 230 may be adhered to the front surface of the window 220 by the second adhesive member AD2. The protective film 230 may perform at least one of functions of prevention of scattering, shock absorption, prevention of scratch, prevention of fingerprint smudges, and prevention of glare on the window 220.

The first adhesive member AD1 and the second adhesive member AD2 may be the same or different from each other, and may each be an optically clear pressure sensitive adhesive (“PSA”), optically clear adhesive (“OCA”) film, or optically clear resin (“OCR”).

The panel lower member 310 may be disposed on the rear surface of the display panel 100. The panel lower member 310 may be adhered to the rear surface of the display panel 100 by the third adhesive member AD3. The third adhesive member AD3 may be a pressure sensitive adhesive (“PSA”). The panel lower member 310 may be a buffer layer for absorbing shock from the outside. The panel lower member 310 absorbs external shock to prevent the display panel 100 from being damaged. The panel lower member 310 may be formed as a single layer or multiple layers. In an embodiment, the panel lower member 310 may include an elastic material such as a rubber, a urethane-based material, a sponge in which an acrylic-based material is foam-molded, or the like, for example.

Although it is illustrated in FIG. 3 that the panel lower member 310 is disposed in the folding area FDA, the disclosure is not limited thereto. In an embodiment, the panel lower member 310 may be removed from the folding area FDA such that the display device 10 is smoothly folded, for example.

The light-blocking member 320 may be disposed on the rear surface of the panel lower member 310. The light-blocking member 320 may be attached to the rear surface of the panel lower member 310 by the fourth adhesive member AD4. FIG. 3 illustrates that the fourth adhesive member AD4 is disposed on the entirety of the rear surface of the panel lower member 310, but the disclosure is not limited thereto. The fourth adhesive member

AD4 may not be disposed in the folding area FDA to reduce the folding stress of the display device 10. In an embodiment, a plurality of fourth adhesive members AD4 may be provided, one of the fourth adhesive members AD4 may be disposed in the first non-folding area NFA1, and another one may be disposed in the second non-folding area NFA2. The fourth adhesive members AD4 may be a pressure sensitive adhesive, for example.

The light-blocking member 320 may be a polymer including or consisting of carbon fiber or glass fiber. When the light-blocking member 320 includes or consists of carbon fiber, the polymer may be epoxy, polyester, polyamide, polycarbonate, polypropylene, polybutylene, or vinyl ester. When the light-blocking member 320 includes glass fiber, the polymer may be epoxy, polyester, polyamide, or vinyl ester.

The thickness of the light-blocking member 320 may be greater than the thickness of the digitizer layer 330 or the thickness of the shielding member 340. In addition, the thickness of the light-blocking member 320 may be greater than the thickness of the display panel 100.

The light-blocking member 320 may include a plurality of bars disposed in the folding area FDA to be easily bent in the folding area FDA. The extension direction of each of the bars may be substantially the same as the extension direction of the first folding line FL1 and the extension direction of the second folding line FL2. That is, each of the bars may extend in the first direction (X-axis direction). The plurality of bars may be disposed in the second direction (Y-axis direction). A slit may be defined between the adjacent bars among the plurality of bars. The width of each of the bars may be less than the width of each of the slits.

The buffer member 360 may be disposed on the rear surface of the light-blocking member 320. The buffer member 360 absorbs external shock to prevent the light-blocking member 320 and the digitizer layer 330 from being damaged. The buffer member 360 may include an elastic material such as a rubber, a urethane-based material, a sponge in which an acrylic-based material is foam-molded, or the like.

The digitizer layer 330 includes a first digitizer layer 331 and a second digitizer layer 332. The first digitizer layer 331 and the second digitizer layer 332 may be disposed on the rear surface of the buffer member 360. The first digitizer layer 331 and the second digitizer layer 332 may be attached to the rear surface of the buffer member 360 by the fifth adhesive members AD5. The fifth adhesive members AD5 may be a pressure sensitive adhesive.

The first digitizer layer 331, the second digitizer layer 332, and the fifth adhesive members AD5 may not be disposed in at least a part of the folding area FDA to reduce the folding stress of the display device 10. In an embodiment, one of the fifth adhesive members AD5 and the first digitizer layer 331 may be disposed in the first non-folding area NFA1, and another one of the fifth adhesive members AD5 and the second digitizer layer 332 may be disposed in the second non-folding area NFA2, for example. The gap between the first digitizer layer 331 and the second digitizer layer 332 may overlap the folding area FDA in the third direction (also referred to as a thickness direction) (Z-axis direction) and may be less than the width of the folding area FDA. The width of the folding area FDA may be the length of the folding area FDA in the second direction (Y-axis direction). The width of any one of the fifth adhesive members AD5 may be less than the width of the first digitizer layer 331 or the second digitizer layer 332.

The first digitizer layer 331 and the second digitizer layer 332 may include electrode patterns for detecting the approach or contact of an electronic pen such as a stylus pen that supports an electromagnetic resonance (“EMR”) method. The first digitizer layer 331 and the second digitizer layer 332 may detect a magnetic field or electromagnetic signal emitted from the electronic pen by the electrode patterns, and determine a point at which the detected magnetic field or electromagnetic signal is largest as a touch coordinate.

The shielding member 340 includes a first shielding member 341 and a second shielding member 342. The first shielding member 341 and the second shielding member 342 may be disposed on the rear surface of the digitizer layer 330.

The first shielding member 341 and the second shielding member 342 may not be disposed in at least a part of the folding area FDA to reduce the folding stress of the display device 10. In an embodiment, the first shielding member 341 may be disposed in the first non-folding area NFA1, and the second shielding member 342 may be disposed in the second non-folding area NFA2, for example. The gap between the first shielding member 341 and the second shielding member 342 may overlap the folding area FDA in the thickness direction (Z-axis direction) and may be less than the width of the folding area FDA.

The first shielding member 341 and the second shielding member 342 include magnetic metal powder, thereby allowing the magnetic field or electromagnetic signal that has passed through the digitizer layer 330 to flow into the first shielding member 341 and the second shielding member 342. The first shielding member 341 and the second shielding member 342 may reduce the likelihood of the magnetic field or electromagnetic signal being emitted to the rear surfaces of the first shielding member 341 and the second shielding member 342.

The heat dissipation member 350 includes a first heat dissipation member 351 and a second heat dissipation member 352. The first heat dissipation member 351 and the second heat dissipation member 352 may be disposed on the rear surface of the shielding member 340.

The first heat dissipation member 351 and the second heat dissipation member 352 may not be disposed in at least a part of the folding area FDA to reduce the folding stress of the display device 10. In an embodiment, the first heat dissipation member 351 may be disposed in the first non-folding area NFA1, and the second heat dissipation member 352 may be disposed in the second non-folding area NFA2, for example. The gap between the first heat dissipation member 351 and the second heat dissipation member 352 may overlap the folding area FDA in the thickness direction (Z-axis direction) and may be less than the width of the folding area FDA.

The first heat dissipation member 351 and the second heat dissipation member 352 may be metal films having superior thermal conductivity such as copper, nickel, ferrite, and silver. Accordingly, heat generated in the display device 10 may be emitted to the outside by the first heat dissipation member 351 and the second heat dissipation member 352.

As shown in FIG. 3, since the light-blocking member 320 is disposed on the digitizer layer 330 and the shielding member 340, it is possible to prevent steps of the electrode patterns of the digitizer layer 330 or the magnetic metal powder of the shielding member 340 from being visually recognized by a user in front of the display device 10.

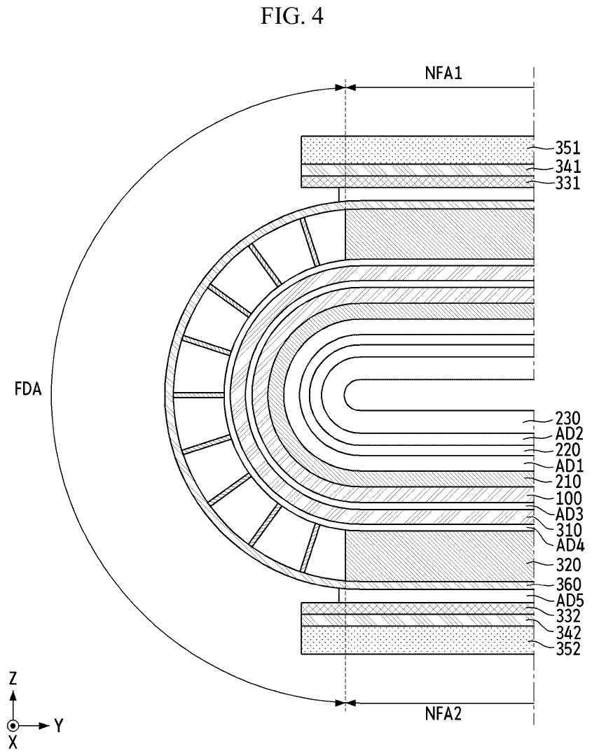

FIG. 4 is a cross-sectional view of an embodiment of the display device 10 in a folded state, and relates to the folding area FDA when the display device of FIG. 3 is in the folded state.

Referring to FIG. 4, when the display device 10 is folded, the first non-folding area NFA1 and the second non-folding area NFA2 may overlap each other in the thickness direction (Z-axis direction). The plurality of digitizer layers 330, shielding members 340, and heat dissipation members 350 may be disposed in separate layers and overlap each other in the thickness direction (Z-axis direction). That is, in the thickness direction (Z-axis direction), the first digitizer layer 331 and the second digitizer layer 332 may overlap each other, the first shielding member 341 and the second shielding member 342 may overlap each other, and the first heat dissipation member 351 and the second heat dissipation member 352 may overlap each other.

The display panel 100 and the front laminated structure 200 may be folded, and compressive stress and tensile stress may be applied to the display panel 100 and the front laminated structure 200 in the folding area FDA. When the display device 10 is folded in the in-folding manner, compressive stress may be applied to the front surfaces of the display panel 100 and the front laminated structure 200, and tensile stress may be applied to the rear surfaces thereof.

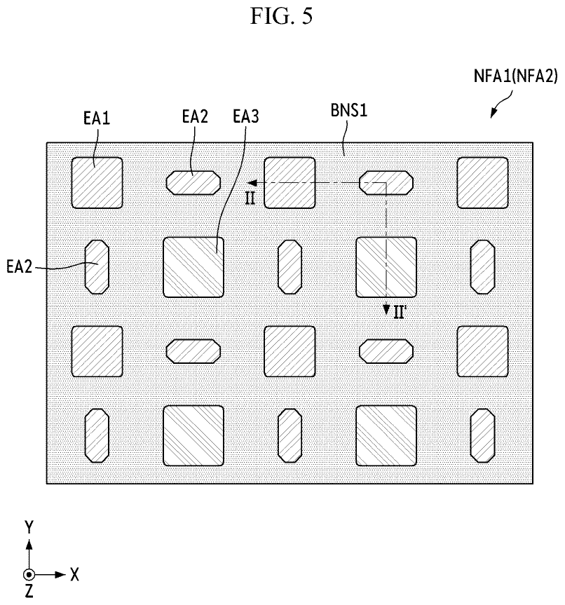

FIG. 5 is a plan view showing an embodiment of the arrangement of emission areas EA1, EA2, and EA3 and a first bank structure BNS1 in the non-folding areas NFA1 and NFA2 of the display device 10.

Referring to FIG. 5, the first bank structure BNS1 may be disposed in the non-folding areas NFA1 and NFA2 of the display area DA. The first bank structure BNS1 may expose the plurality of emission areas while covering the non-folding areas NFA1 and NFA2.

The emission areas EA1, EA2, and EA3 may include a first emission area EA1, a second emission area EA2, and a third emission area EA3 emitting light of different colors. The first to third emission areas EA1, EA2, and EA3 may emit red, green, or blue light, respectively, and the color of the light emitted from each of the emission areas EA1, EA2, and EA3 may be different depending on the type of light-emitting elements ED1, ED2, and ED3 (refer to FIG. 6) to be described later. In an embodiment, the first emission area EA1 may emit first light, the second emission area EA2 may emit second light, and the third emission area EA3 may emit third light. However, the disclosure is not limited thereto.

The plurality of emission areas EA1, EA2, and EA3 may be disposed in a PenTile™ type, e.g., a diamond PenTile™ type. In an embodiment, the first emission area EA1 and the second emission area EA2 may be spaced apart from each other, and may be disposed alternately in the first direction (X-axis direction) and the second direction (Y-axis direction), for example. The third emission area EA3 may be spaced apart from the plurality of adjacent second emission areas EA2 in the first direction (X-axis direction) and the second direction (Y-axis direction). The first emission area EA1 and the third emission area EA3 may be disposed alternately along any one direction in the plane formed by the first direction (X-axis direction) and the second direction (Y-axis direction).

The number of the second emission areas EA2 may be greater than the number of the first emission areas EA1 and the third emission areas EA3. In an embodiment, the number of the first emission areas EA1 may be the same as that of the third emission areas EA3, and the number of the second emission areas EA2 may be twice that of the first emission areas EA1. The second emission areas EA2 may be arranged at regular intervals along the first direction (X-axis direction) and the second direction (Y-axis direction), and the arrangement angles may vary. In an embodiment, each of the second emission areas EA2 may be disposed rotated by 90°. Some of the second emission areas EA2 may be also referred to as fourth emission areas. The fourth emission area and the second emission area may emit light of the same color. The second emission areas may be aligned in the first direction (X-axis direction) with respect to the first emission area EA1 or the third emission area EA3. The fourth emission areas may be aligned in the second direction (Y-axis direction) with respect to the first emission area EA1 or the third emission area EA3.

The first to third emission areas EA1, EA2, and EA3 may each be defined by a pixel defining layer PDL (refer to FIG. 4), which will be described later.

FIG. 6 is a cross-sectional view of an embodiment of the display device 10 taken along line II-II′ of FIG. 5.

Referring to FIG. 6, the display panel 100 may include a substrate SUB, a thin film transistor layer TFTL, a light-emitting element layer EML, a thin film encapsulation layer TFEL, and a color filter layer CFL.

The substrate SUB may be a base substrate or a base member. The substrate SUB may be a flexible substrate which may be bent, folded or rolled. In an embodiment, the substrate SUB may include a polymer resin such as polyimide (“PI”), for example, but is not limited thereto. In another embodiment, the substrate SUB may include a glass material or a metal material.

The thin film transistor layer TFTL may be disposed on the substrate SUB. The thin film transistor layer TFTL may include lines, a plurality of thin film transistors constituting a pixel circuit of pixels. The thin film transistor layer TFTL may be disposed in the display area DA and the non-display area NDA. Thin film transistors, scan lines, data lines, and power lines of each of the pixels of the thin film transistor layer TFTL may be disposed in the display area DA. Scan control lines, lead lines, and fan-out lines of the thin film transistor layer TFTL may be disposed in the non-display area NDA.

The thin film transistor layer TFTL may include a first buffer layer BF1, a lower metal layer BML, a second buffer layer BF2, a thin film transistor TFT, a gate insulating layer GI, a first inter-insulating layer ILD1, a capacitor electrode CPE, a second inter-insulating layer ILD2, a first connection electrode CNE1, a first passivation layer PAS1, a second connection electrode CNE2, and a second passivation layer PAS2.

The first buffer layer BF1 may be disposed on the substrate SUB. The first buffer layer BF1 may include an inorganic film capable of preventing penetration of air or moisture. In an embodiment, the first buffer layer BF1 may include a plurality of inorganic films alternately stacked, for example.

The lower metal layer BML may be disposed on the first buffer layer BF1. In an embodiment, the lower metal layer BML may be formed as a single layer or multiple layers including or consisting of any one of molybdenum (Mo), aluminum (Al), chromium (Cr), gold (Au), titanium (Ti), nickel (Ni), neodymium (Nd) and copper (Cu) or any alloys thereof.

The second buffer layer BF2 may cover the first buffer layer BF1 and the lower metal layer BML. The second buffer layer BF2 may include an inorganic film capable of preventing penetration of air or moisture. In an embodiment, the second buffer layer BF2 may include a plurality of inorganic films alternately stacked, for example.

The thin film transistor TFT may be disposed on the second buffer layer BF2, and may constitute a pixel circuit of each of a plurality of pixels. In an embodiment, the thin film transistor TFT may be a switching transistor or a driving transistor of the pixel circuit, for example. The thin film transistor TFT may include a semiconductor layer ACT, a source electrode SE, a drain electrode DE, and a gate electrode GE.

The semiconductor layer ACT may be disposed on the second buffer layer BF2. The semiconductor layer ACT may overlap the lower metal layer BML and the gate electrode GE in the thickness direction (Z-axis direction), and may be insulated from the gate electrode GE by the gate insulating layer GI. In a part of the semiconductor layer ACT, a material of the semiconductor layer ACT may be made into a conductor to form the source electrode SE and the drain electrode DE.

The gate electrode GE may be disposed on the gate insulating layer GI. The gate electrode GE may overlap the semiconductor layer ACT in the thickness direction (Z-axis direction) with the gate insulating layer GI interposed therebetween.

The gate insulating layer GI may be disposed on the semiconductor layer ACT. In an embodiment, the gate insulating layer GI may cover the semiconductor layer ACT and the second buffer layer BF2 to insulate the gate electrode GE from the semiconductor layer ACT, for example. The gate insulating layer GI may include a contact hole through which the first connection electrode CNE1 passes.

The first inter-insulating layer ILD1 may cover the gate electrode GE and the gate insulating layer GI. The first inter-insulating layer ILD1 may include a contact hole through which the first connection electrode CNE1 passes. The contact hole of the first inter-insulating layer ILD1 may be connected to the contact hole of the gate insulating layer GI and the contact hole of the second inter-insulating layer ILD2.

The capacitor electrode CPE may be disposed on the first inter-insulating layer ILD1. The capacitor electrode CPE may overlap the gate electrode GE in the thickness direction (Z-axis direction). The capacitor electrode CPE and the gate electrode GE may form a capacitance.

The second inter-insulating layer ILD2 may cover the capacitor electrode CPE and the first inter-insulating layer ILD1. The second inter-insulating layer ILD2 may include a contact hole through which the first connection electrode CNE1 passes. The contact hole of the second inter-insulating layer ILD2 may be connected to the contact hole of the first inter-insulating layer ILD1 and the contact hole of the gate insulating layer GI.

The first connection electrode CNE1 may be disposed on the second inter-insulating layer ILD2. The first connection electrode CNE1 may electrically connect the drain electrode DE of the thin film transistor TFT to the second connection electrode CNE2.

The first connection electrode CNE1 may be inserted into a contact hole defined in the second inter-insulating layer ILD2, the first inter-insulating layer ILD1, and the gate insulating layer GI to contact the drain electrode DE of the thin film transistor TFT.

The first passivation layer PAS1 may cover the first connection electrode CNE1 and the second inter-insulating layer ILD2. The first passivation layer PAS1 may protect the thin film transistor TFT. The first passivation layer PAS1 may include a contact hole through which the second connection electrode CNE2 passes.

The second connection electrode CNE2 may be disposed on the first passivation layer PAS1. The second connection electrode CNE2 may electrically connect the first connection electrode CNE1 to a pixel electrode AE1, AE2, AE3 of the light-emitting element ED. The second connection electrode CNE2 may be inserted into a contact hole defined in the first passivation layer PAS1 to contact the first connection electrode CNE1.

The second passivation layer PAS2 may cover the second connection electrode CNE2 and the first passivation layer PAS1. The second passivation layer PAS2 may include a contact hole through which the pixel electrode AE1, AE2, AE3 of the light-emitting element ED passes.

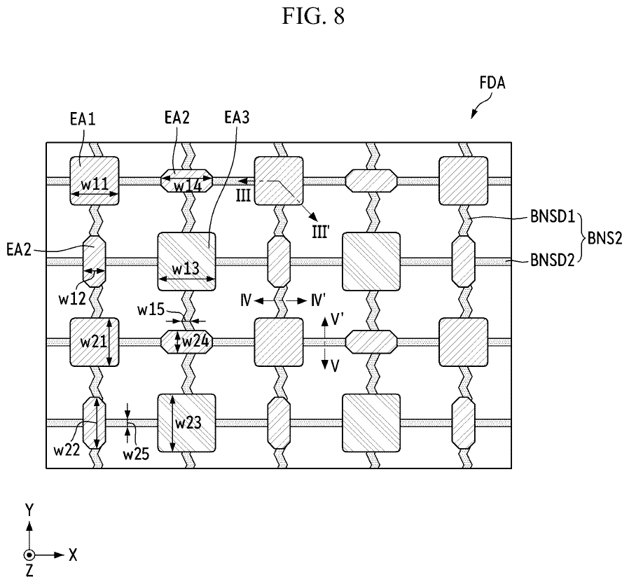

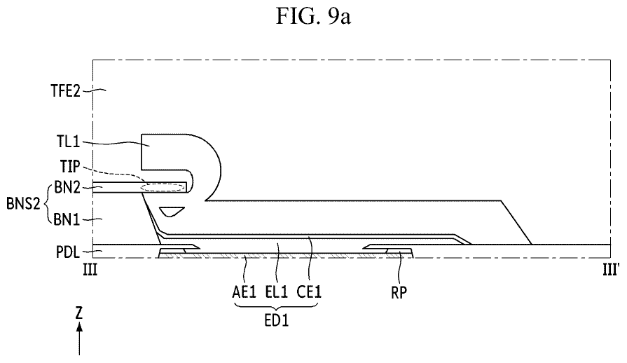

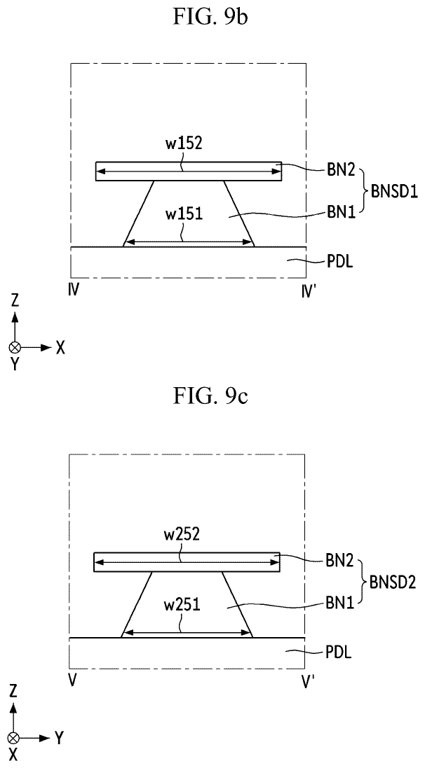

The light-emitting element layer EML may be disposed on the thin film transistor layer TFTL. The light-emitting element layer EML may include a plurality of light-emitting elements ED that emit light, the pixel defining layer PDL that defines pixels or the emission areas EA1, EA2, and EA3, and bank structures BNS1 and BNS2 (refer to FIGS. 8 and 9A to 9C).

The light-emitting elements ED may include the pixel electrodes AE1, AE2, and AE3, light-emitting layers EL1, EL2, and EL3, and common electrodes CE1, CE2, and CE3.

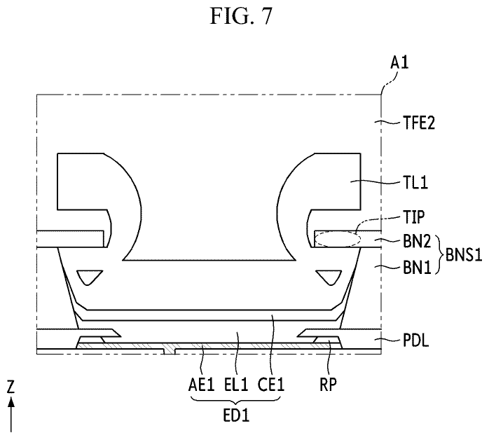

FIG. 7 is an enlarged view showing a first emission area of FIG. 6, specifically, area A1.

Referring to FIG. 7 in addition to FIG. 6, the display device 10 may include the plurality of emission areas EA1, EA2, and EA3 disposed in the display area DA. The emission areas EA1, EA2, and EA3 may be defined as areas in which the pixel electrodes AE1, AE2, and AE3, the light-emitting layers EL1, EL2, and EL3, and the common electrodes CE1, CE2, and CE3 overlap in the thickness direction of the substrate SUB. The emission areas EA1, EA2, and EA3 may include the first emission area EA1, the second emission area EA2, and the third emission area EA3 spaced apart from each other and emitting light of the same or different colors.

In an embodiment, the areas or sizes of the first to third emission areas EA1, EA2, and EA3 may be different from each other. In an embodiment, the area of the third emission area EA3 may be larger than the areas of the first emission area EA1 and the second emission area EA2, and the area of the first emission area EA1 may be larger than the area of the second emission area EA2, for example. However, the disclosure is not limited thereto. In the display device 10, the areas or sizes of the first to third emission areas EA1, EA2, and EA3 may be the same. The intensity of light emitted from the corresponding emission areas EA1, EA2, and EA3 may vary according to the areas of the emission areas EA1, EA2, and EA3, and the areas of the emission areas EA1, EA2, and EA3 may be adjusted to control the color of the screen displayed on the display device 10.

In the display device 10, one first emission area EA1, one second emission area EA2, and one third emission area EA3 disposed adjacent to each other may form one pixel group. One pixel group may include the emission areas EA1, EA2, and EA3 emitting light of different colors to express a white grayscale. However, the disclosure is not limited thereto, and the combination of the emission areas EA1, EA2, and EA3 constituting one pixel group may be variously modified depending on the arrangement of the emission areas EA1, EA2, and EA3, the color of the light emitted from the emission areas EA1, EA2, and EA3, or the like.

The display device 10 may include the plurality of light-emitting elements ED1, ED2, and ED3 disposed in the different emission areas EA1, EA2, and EA3. The light-emitting elements ED1, ED2, and ED3 may include the first light-emitting element ED1 disposed in the first emission area EA1, the second light-emitting element ED2 disposed in the second emission area EA2, and the third light-emitting element ED3 disposed in the third emission area EA3.

The light-emitting elements ED1, ED2, and ED3 may include the pixel electrodes AE1, AE2, and AE3, the light-emitting layers EL1, EL2, and EL3, and the common electrodes CE1, CE2, and CE3, respectively, and the light-emitting elements ED1, ED2, and ED3 disposed in the different emission areas EA1, EA2, and EA3 may emit lights of different colors depending on the materials of the light-emitting layers EL1, EL2, and EL3. In an embodiment, the first light-emitting element ED1 disposed in the first emission area EA1 may emit red light having a peak wavelength within a range of 610 nanometers (nm) to 650 nm, the second light-emitting element ED2 disposed in the second emission area EA2 may emit green light having a peak wavelength within a range of 510 nm to 550 nm, and the third light-emitting element ED3 disposed in the third emission area EA3 may emit blue light having a peak wavelength within a range of 440 nm to 480 nm. The first to third emission areas EA1, EA2, and EA3 constituting one pixel may respectively include the light-emitting elements ED1, ED2, and ED3 emitting lights of different colors to express a white grayscale, for example.

The pixel electrodes AE1, AE2, and AE3 may be disposed on the second passivation layer PAS2. The pixel electrodes AE1, AE2, and AE3 may be disposed in the plurality of emission areas EA1, EA2, and EA3, respectively. The pixel electrodes AE1, AE2, and AE3 may include a first pixel electrode AE1 disposed in the first emission area EA1, a second pixel electrode AE2 disposed in the second emission area EA2, and a third pixel electrode AE3 disposed in the third emission area EA3. The first pixel electrode AE1, the second pixel electrode AE2, and the third pixel electrode AE3 may be spaced apart from each other on the second passivation layer PAS2.

The pixel electrodes AE1, AE2, and AE3 may be electrically connected to the drain electrode DE of the thin film transistor TFT through the first and second connection electrodes CNE1 and CNE2. The edges of the pixel electrodes AE1, AE2, and AE3 spaced apart from each other may be covered by the pixel defining layer PDL, so that the first to third pixel electrodes AE1, AE2, and AE3 may be insulated from each other.

The pixel electrodes AE1, AE2, and AE3 may include a transparent electrode material and/or conductive metal material, and may have a single-layer or multilayer structure. The metal material may be at least one of silver (Ag), copper (Cu), aluminum (Al), nickel (Ni), lanthanum (La), titanium (Ti), or titanium nitride (TiN). The transparent electrode material may be at least one of indium tin oxide (“ITO”), indium zinc oxide (“IZO”), or indium tin zinc oxide (“ITZO”).

The pixel defining layer PDL may be disposed on the second passivation layer PAS2, a residual pattern RP, and the pixel electrodes AE1, AE2, and AE3. The pixel defining layer PDL may be disposed on the entirety of the second passivation layer PAS2, and may cover the side surfaces of the pixel electrodes AE1, AE2, and AE3 and the residual pattern RP to partially expose the top surfaces of the pixel electrodes AE1, AE2, and AE3. In an embodiment, the pixel defining layer PDL may expose the first pixel electrode AE1 in the first emission area EA1, and a first light-emitting layer EL1 may be directly disposed on the first pixel electrode AE1, for example.

The pixel defining layer PDL may include an inorganic insulating material. The pixel defining layer PDL may include at least one of silicon nitride, silicon oxynitride, silicon oxide, titanium oxide, aluminum oxide, tantalum oxide, hafnium oxide, zinc oxide, or amorphous silicon, but the disclosure is not limited thereto. The pixel defining layer PDL may have a single-layer or multilayer structure.

In an embodiment, the pixel defining layer PDL may be disposed on the pixel electrodes AE1, AE2, and AE3, and may be spaced apart from the top surfaces of the pixel electrodes AE1, AE2, and AE3. The pixel defining layer PDL may partially overlap the top surfaces of the pixel electrodes AE1, AE2, and AE3 in the thickness direction (Z-axis direction) of the substrate SUB but may not be in direct contact with them, and the residual pattern RP may be disposed between the bottom surface of the pixel defining layer PDL and the top surfaces of the pixel electrodes AE1, AE2, and AE3. However, the pixel defining layer PDL may be in direct contact with the side surfaces of the pixel electrodes AE1, AE2, and AE3.

The residual pattern RP may be disposed on the edge of each of the pixel electrodes AE1, AE2, and AE3. The pixel defining layer PDL may not be in direct contact with the top surfaces of the pixel electrodes AE1, AE2, and AE3 due to the residual pattern RP. The residual pattern RP may include a metal or oxide semiconductor material. In the drawings, only the side surface of the residual pattern RP facing the emission areas EA1, EA2, and EA3 is illustrated as being more recessed than the side surface of the pixel defining layer PDL, but the disclosure is not limited thereto. The side surface of the residual pattern RP may protrude from the side surface of the pixel defining layer PDL toward the emission areas EA1, EA2, and EA3, or may be aligned therewith. The side surface of the pixel defining layer PDL may be a side surface disposed at the outermost side toward the emission areas EA1, EA2, and EA3.

The light-emitting layers EL1, EL2, and EL3 may be disposed on the pixel electrodes AE1, AE2, and AE3, respectively. The light-emitting layers EL1, EL2, and EL3 may be organic light-emitting layers including or consisting of an organic material, and may be formed on the pixel electrodes AE1, AE2, and AE3, respectively, by the deposition process. The light-emitting layers EL1, EL2, and EL3 may have a multilayer structure, and each of a hole injection material, a hole transport material, a light-emitting material, an electron transport material, and/or an electron injection material may form a layer. When the thin film transistor TFT applies a predetermined voltage to the pixel electrodes AE1, AE2, and AE3 of the light-emitting elements ED1, ED2, and ED3, and the common electrodes CE1, CE2, and CE3 of the light-emitting elements ED1, ED2, and ED3 receive a common voltage or a cathode voltage, holes and electrons may be injected and transported, and may be combined with each other to emit light in the light-emitting layers EL1, EL2, and EL3.

The light-emitting layers EL1, EL2, and EL3 may include the first light-emitting layer EL1, a second light-emitting layer EL2, and a third light-emitting layer EL3 disposed in the different emission areas EA1, EA2, and EA3. The first light-emitting layer EL1 may be disposed on the first pixel electrode AE1 in the first emission area EA1, the second light-emitting layer EL2 may be disposed on the second pixel electrode AE2 in the second emission area EA2, and the third light-emitting layer EL3 may be disposed on the third pixel electrode AE3 in the third emission area EA3. The plurality of light-emitting layers EL1, EL2, and EL3 may emit lights of different colors, or one light-emitting layer EL1, EL2, or EL3 may emit mixed light. In an embodiment, the first light-emitting layer EL1 may emit red light, the second light-emitting layer EL2 may emit green light, and the third light-emitting layer EL3 may emit blue light.

The light-emitting layers EL1, EL2, and EL3 may be disposed on the top surface of the pixel defining layer PDL. In an embodiment, a part of the light-emitting layers EL1, EL2, and EL3 may be disposed in the space between the pixel electrodes AE1, AE2, and AE3 and the pixel defining layer PDL. In an embodiment, the light-emitting layers EL1, EL2, and EL3 may contact the pixel defining layer PDL, the residual pattern RP, and the pixel electrodes AE1, AE2, and AE3.

The common electrodes CE1, CE2, and CE3 may be disposed on the light-emitting layers EL1, EL2, and EL3, respectively. The common electrodes CE1, CE2, and CE3 may include a transparent conductive material, so that the light generated in the light-emitting layers EL1, EL2, and EL3 may be emitted. The common electrodes CE1, CE2, and CE3 may receive a common voltage or a relatively low potential voltage. When the pixel electrodes AE1, AE2, and AE3 receive the voltage corresponding to a data voltage and the common electrodes CE1, CE2, and CE3 receive the relatively low potential voltage, a potential difference is formed between the pixel electrodes AE1, AE2, and AE3 and the common electrodes CE1, CE2, and CE3, so that the light-emitting layers EL1, EL2, and EL3 may emit light.

The common electrodes CE1, CE2, and CE3 may include a first common electrode CE1, a second common electrode CE2, and a third common electrode CE3 disposed in the different emission areas EA1, EA2, and EA3. The first common electrode CE1 may be disposed on the first light-emitting layer EL1 in the first emission area EA1, the second common electrode CE2 may be disposed on the second light-emitting layer EL2 in the second emission area EA2, and the third common electrode CE3 may be disposed on the third light-emitting layer EL3 in the third emission area EA3. The first to third common electrodes CE1, CE2, and CE3 may be spaced apart from each other.

A capping layer (not shown) may be selectively disposed on the common electrodes CE1, CE2, and CE3. The capping layer may include an organic or inorganic insulating material to cover patterns disposed on the light-emitting elements ED1, ED2, and ED3. The capping layer may prevent the light-emitting elements ED1, ED2, and ED3 from being damaged by external air. In an embodiment, the capping layer may include an organic material such as a-NPD, NPB, TPD, m-MTDATA, Alq₃, and/or CuPc, or an inorganic material such as lithium fluoride, aluminum oxide, titanium oxide, tantalum oxide, hafnium oxide, zinc oxide, silicon oxide, silicon nitride, and/or silicon oxynitride.

The display device 10 may include the first bank structure BNS1 disposed on the pixel defining layer PDL. The first bank structure BNS1 may be formed in the non-folding areas NFA1 and NFA2. The first bank structure BNS1 may have a structure in which the banks BN1 and BN2 including different materials are sequentially stacked, may include the plurality of openings including the emission areas EA1, EA2, and EA3, and may be disposed to overlap the light-blocking area of the color filter layer CFL to be described later. The light-emitting elements ED1, ED2, and ED3 of the display device 10 may be disposed to overlap the openings of the first bank structure BNS1.

The first bank BN1 may be disposed on the pixel defining layer PDL. The side surface of the first bank BN1 may be recessed more than the side surface of the pixel defining layer PDL in a direction opposite to the direction facing the emission areas EA1, EA2, and EA3. The side surface of the first bank BN1 may be recessed more than the side surface of the second bank BN2 to be described later in a direction opposite to a direction facing the emission areas EA1, EA2, and EA3.

In an embodiment, the first bank BN1 may include a conductive metal material. In an embodiment, the first bank BN1 may include aluminum (Al), an oxide of aluminum (A1), or an alloy of aluminum (Al).

The common electrodes CE1, CE2, and CE3 may contact the first bank BN1 to be electrically connected thereto. The common electrodes CE1, CE2, and CE3 that are spaced apart from each other may be electrically connected to each other via the first bank BN1.

The light-emitting layers EL1, EL2, and EL3 may be in direct contact with the side surface of the first bank BN1. The contact area between the common electrodes CE1, CE2, and CE3 and the side surface of the first bank BN1 may be larger than the contact area between the light-emitting layers EL1, EL2, and EL3 and the side surface of the first bank

BN1. The common electrodes CE1, CE2, and CE3 may be disposed in larger areas on the side surface of the first bank BN1 compared to the light-emitting layers EL1, EL2, and EL3, or may be disposed at higher positions on the side surface of the first bank BN1 compared to the light-emitting layers EL1, EL2, and EL3. Since the common electrodes CE1, CE2, and CE3 of the different light-emitting elements ED1, ED2, and ED3 are electrically connected through the first bank BN1, it may be advantageous that they contact the first bank BN1 in larger areas.

The first bank BN1 may have a top surface at a higher position than those of the common electrodes CE1, CE2, and CE3. The height from the substrate SUB to the top surface of the first bank BN1 may be greater than the height from the substrate SUB to the common electrodes CE1, CE2, and CE3.

The second bank BN2 may be disposed on the first bank BN1. Referring to FIGS. 6 and 7, the second bank BN2 may define openings overlapping the respective emission areas EA1, EA2, and EA3, and each opening may include a side surface. The second bank BN2 may include a tip (or eave) TIP, which is an area protruding compared to the first bank BN1. The side surface of the second bank BN2 may protrude more toward the emission areas EA1, EA2, and EA3 than the side surface of the first bank BN1.

As the side surface of the second bank BN2 has a shape protruding more toward the emission areas EA1, EA2, and EA3 than the side surface of the first bank BN1, an undercut structure of the first bank BN1 may be formed under the tip TIP of the second bank BN2.

In the display device 10 in an embodiment, as the first bank structure BNS1 includes the tip TIP protruding toward the emission areas EA1, EA2, and EA3, the light-emitting layers EL1, EL2, and EL3 and the common electrodes CE1, CE2, and CE3 that are spaced apart from each other may be formed through deposition and etching processes instead of a mask process. Further, it is possible to individually form different layers in the different emission areas EA1, EA2, and EA3 by the deposition process. In an embodiment, even when the light-emitting layers EL1, EL2, and EL3 of the light-emitting elements ED1, ED2, and ED3 and the common electrodes CE1, CE2, and CE3 are formed by a deposition process using no mask, the deposited materials may be disconnected by the tip TIP of the second bank BN2 without being connected between the emission areas EA1, EA2, and EA3, for example. By a process of forming a material for forming a predetermined layer on the entirety of the surface of the display device 10 and then etching and removing the layer formed in an undesired region, it is possible to individually form different layers in the different emission areas EA1, EA2, and EA3. In the display device 10, an unnecessary configuration may be omitted and the area of the non-display area NDA may be minimized.

The second bank BN2 may include a metal material different from the metal material of the first bank BN1. Desirably, the metal material of the second bank BN2 may be a material that is removed by dry etching together with the metal material of the first bank BN1, but has an etching rate much slower than that of the first bank BN1 when wet-etched or is not etched by wet etching. In an embodiment, the second bank BN2 may include titanium (Ti), an oxide of titanium (Ti), or an alloy of titanium (Ti).

The tip TIP of the second bank BN2 may overlap the common electrodes CE1, CE2, and CE3, the light-emitting layers EL1, EL2, and EL3, and the pixel defining layer PDL in the thickness direction (Z-axis direction). The common electrodes CE1, CE2, and CE3 may be formed under the bottom surface of the tip TIP of the second bank BN2. One end and an opposite end of each of the common electrodes CE1, CE2, and CE3 may overlap the second bank BN2 in the thickness direction (Z-axis direction).

The thin film encapsulation layer TFEL may be disposed on the light-emitting elements ED1, ED2, and ED3 and the bank structures BNS1 and BNS2, and may cover the plurality of light-emitting elements ED1, ED2, and ED3 and the bank structures BNS1 and BNS2. The thin film encapsulation layer TFEL may include at least one inorganic film to prevent oxygen or moisture from permeating into the light-emitting element layer EML. The thin film encapsulation layer TFEL may include at least one organic film to protect the light-emitting element layer EML from foreign substances such as dust.

In an embodiment, the thin film encapsulation layer TFEL may include a lower inorganic encapsulation layer TFE1, an organic encapsulation layer TFE2, and an upper inorganic encapsulation layer TFE3 that are sequentially stacked.

Each of the lower inorganic encapsulation layer TFE1 and the upper inorganic encapsulation layer TFE3 may include one or more inorganic insulators. The inorganic insulating material may be any one of silicon oxide, silicon nitride, and silicon oxynitride, and may include, e.g., aluminum oxide, titanium oxide, tantalum oxide, hafnium oxide, zinc oxide, silicon oxide, silicon nitride, and/or silicon oxynitride.

The organic encapsulation layer TFE2 may include a polymer-based material. In embodiments, the polymer-based material may include acrylic resin, epoxy resin, polyimide, polyethylene or the like. In an embodiment, the organic encapsulation layer TFE2 may include an acrylic resin, e.g., polymethyl methacrylate, polyacrylic acid, or the like, for example. The organic encapsulation layer TFE2 may be formed by curing a monomer or applying a polymer.

The lower inorganic encapsulation layer TFE1 may be disposed on the light-emitting elements ED1, ED2, and ED3, and the bank structures BNS1 and BNS2. The lower inorganic encapsulation layer TFE1 may include a first inorganic layer TL1, a second inorganic layer TL2, and a third inorganic layer TL3 disposed to correspond to the different emission areas EA1, EA2, and EA3, respectively. The first inorganic layer TL1, the second inorganic layer TL2, and the third inorganic layer TL3 may include an inorganic insulating material to cover the light-emitting elements ED1, ED2, and ED3, respectively. The first inorganic layer TL1, the second inorganic layer TL2, and the third inorganic layer TL3 may prevent the light-emitting elements ED1, ED2, and ED3 from being damaged by external air.

Since the lower inorganic encapsulation layer TFE1 (TL1, TL2, TL3) may be formed through a chemical vapor deposition (“CVD”) method, it may be formed along a stepped portion of a layer to be deposited. In an embodiment, the first inorganic layer TL1, the second inorganic layer TL2, and the third inorganic layer TL3 may form thin films even under the undercut by the tips of the bank structures BNS1 and BNS2, for example. The lower inorganic encapsulation layers TL1, TL2, and TL3 may be disposed along the top, side, and bottom surfaces of the second bank BN2, the side surface of the first bank BN1, and the top surfaces of the common electrodes CE1, CE2, and CE3. The lower inorganic encapsulation layers TL1, TL2, and TL3 may contact the bottom surface of the second bank BN2, thereby preventing moisture permeation from external air.

The first inorganic layer TL1 may be disposed only on the first light-emitting element ED1 and the pixel defining layer PDL and the bank structures BNS1 and BNS2 in the vicinity thereof without overlapping the second light-emitting element ED2 and the third light-emitting element ED3. The second inorganic layer TL2 may be disposed only on the second light-emitting element ED2 and the pixel defining layer PDL and the bank structures BNS1 and BNS2 in the vicinity thereof without overlapping the first light-emitting element ED1 and the third light-emitting element ED3. The third inorganic layer TL3 may be disposed only on the third light-emitting element ED3 and the pixel defining layer PDL and the bank structures BNS1 and BNS2 in the vicinity thereof without overlapping the first light-emitting element ED1 and the second light-emitting element ED2.

The first inorganic layer TL1 may be formed after the first common electrode CE1 is formed, the second inorganic layer TL2 may be formed after the second common electrode CE2 is formed, and the third inorganic layer TL3 may be formed after the third common electrode CE3 is formed. The first inorganic layer TL1, the second inorganic layer TL2, and the third inorganic layer TL3 may be spaced apart from each other on the bank structures BNS1 and BNS2.

The lower inorganic encapsulation layers TL1, TL2, and TL3 may be disposed on the light-emitting elements ED1, ED2, and ED3 and the top and bottom surfaces of the second bank BN2 in the vicinity thereof, while being spaced apart from the top surface of the second bank BN2. That is, the lower inorganic encapsulation layers TL1, TL2, and TL3 may have an undercut structure on the second bank BN2. The separation space between the lower inorganic encapsulation layers TL1, TL2, and TL3 and the top surface of the second bank BN2 may be a space from which materials of the light-emitting layers EL1, EL2, and EL3 and the common electrodes CE1, CE2, and CE3 entirely deposited have been removed.

The organic encapsulation layer TFE2 is disposed on the second bank BN2 and the lower inorganic encapsulation layers TL1, TL2, and TL3. A part of the organic encapsulation layer TFE2 may be disposed in the separation space between the lower inorganic encapsulation layers TL1, TL2, and TL3 and the top surface of the second bank BN2. In the area where the second bank BN2 overlaps the lower inorganic encapsulation layers TL1, TL2, and TL3, the second bank BN2, the organic encapsulation layer TFE2, and the lower inorganic encapsulation layers TL1, TL2, and TL3 may be sequentially disposed. In the tip TIP area, the organic encapsulation layer TFE2 and the lower inorganic encapsulation layers TL1, TL2, and TL3 may be sequentially disposed on the second bank BN2, and the organic encapsulation layer TFE2 may also be disposed on the lower inorganic encapsulation layers TL1, TL2, and TL3. In other words, a part of the organic encapsulation layer TFE2 may be disposed between the top surface of the second bank BN2 and the lower inorganic encapsulation layers TL1, TL2, and TL3 on the tip TIP of the second bank BN2, and another part thereof may be disposed on the lower inorganic encapsulation layers TL1, TL2, and TL3.

A reinforcement layer (not shown) may be selectively disposed between the lower inorganic encapsulation layers TL1, TL2, and TL3 and the organic encapsulation layer TFE2. The reinforcement layer may be a common layer formed over the entirety of the surface of the substrate SUB. The reinforcement layer may include an inorganic material, e.g., any one or more of silicon oxide, silicon nitride, and silicon oxynitride.

The upper inorganic encapsulation layer TFE3 may be disposed on the organic encapsulation layer TFE2. The upper inorganic encapsulation layer TFE3 may include aluminum oxide, titanium oxide, tantalum oxide, hafnium oxide, zinc oxide, silicon oxide, silicon nitride, and/or silicon oxynitride.

The color filter layer CFL may be disposed on the thin film encapsulation layer TFEL. The color filter layer CFL may include a plurality of color filters respectively corresponding to the plurality of emission areas. Each of the color filters may selectively transmit light of a predetermined wavelength and may block or absorb light of a different wavelength. The color filter layer CFL may absorb a part of light coming from the outside of the display device 10 to reduce reflected light due to external light. Accordingly, the color filter layer CFL may prevent color distortion caused by reflection of the external light.

Since the color filter layer CFL is directly disposed on the thin film encapsulation layer TFEL, a separate substrate for the color filter layer CFL may not be desired in the display device 10. Accordingly, the thickness of the display device 10 may be relatively small.

The color filter layer CFL may include the plurality of color filters CF1, CF2, and CF3 disposed on the emission areas EA1, EA2, and EA3. Each of the plurality of color filters CF1, CF2, and CF3 may include a filtering pattern area and a light-blocking area. The filtering pattern area may be formed to overlap the emission areas EA1, EA2, and EA3, and may constitute a light exit area where light emitted from the emission areas EA1, EA2, and EA3 is outputted. The light-blocking area is an area in which the plurality of color filters CF1, CF2, and CF3 are stacked so that light cannot be transmitted.

The color filters CF1, CF2, and CF3 may include the first color filter CF1, the second color filter CF2, and the third color filter CF3 disposed to correspond to the different emission areas EA1, EA2, and EA3, respectively. The color filters CF1, CF2, and CF3 may include a colorant such as a dye or a pigment that absorbs light in a wavelength band other than a predetermined wavelength band, and may be disposed to correspond to the color of the light emitted from the emission areas EA1, EA2, and EA3. In an embodiment, the first color filter CF1 may be a red color filter that is disposed to overlap the first emission area EA1 and transmits only the red light, for example. The second color filter CF2 may be a green color filter that is disposed to overlap the second emission area EA2 and transmits only the green light, and the third color filter CF3 may be a blue color filter that is disposed to overlap the third emission area EA3 and transmits only the blue light.

In the display device 10, the color filters CF1, CF2, and CF3 are disposed to overlap each other, so that the intensity of the reflected light by external light may be reduced. Furthermore, the color of the reflected light by the external light may be controlled by adjusting the arrangement, shape, and area of the color filters CF1, CF2, and CF3 in a plan view.

An overcoat layer OC may be disposed on the color filters CF1, CF2, and CF3 to flatten the tops of the color filters CF1, CF2, and CF3. The overcoat layer OC may be a colorless light transmissive layer that does not have a color in a visible light band. In an embodiment, the overcoat layer OC may include a colorless light transmissive organic material such as an acrylic resin, for example.

In some embodiments, the display device 10 may further include an optical device. The optical device may emit or receive light in infrared, ultraviolet, and visible light bands. In an embodiment, the optical device may be an optical sensor that detects light incident on the display device 10 such as a proximity sensor, an illuminance sensor, a camera sensor, a fingerprint sensor, or an image sensor, for example.

FIG. 8 is a plan view showing the arrangement of the emission areas EA1, EA2, and EA3 and the second bank structure BNS2 in the folding area FDA of the display device 10. FIGS. 9A to 9C are cross-sectional views of the display device in an embodiment taken along lines III-III′, IV-IV′, and V-V′ of FIG. 8, respectively. FIG. 9A focuses on the light-emitting element layer EML. FIGS. 9B and 9C focus on the second bank structure BNS2.

Referring to FIG. 8, the second bank structure BNS2 having a bridge shape may be disposed between the emission areas EA1, EA2, and EA3 that are spaced apart from each other. The second bank structure BNS2 in the folding area FDA may be formed simultaneously with the first bank structure BNS1 in the non-folding areas NFA1 and NFA2.

The second bank structure BNS2 may include a first bridge bank BNSD1 mainly extending in the folding direction or the second direction (Y-axis direction) and a second bridge bank BNSD2 extending the first direction (X-axis direction) that crosses the folding direction or the second direction (Y-axis direction). The first bridge bank BNSD1 and the second bridge bank BNSD2 may each be provided in plural number. One bridge bank may be disposed between two of the emission areas EA1, EA2, and EA3.

The first to third emission areas EA1, EA2, and EA3 may be aligned in the first direction (X-axis direction) and the second direction (Y-axis direction), and each emission area may be disposed at a grid point of grid patterns that intersect in the first direction (X-axis direction) and the second direction (Y-axis direction). The first emission areas EA1 and the second emission areas EA2, which are aligned in the folding direction or the second direction (Y-axis direction), are alternately disposed, and the first bridge bank BNSD1 is disposed between the first emission area EA1 and the second emission area EA2. The second emission areas EA2 and the third emission areas EA3, which are aligned in the folding direction or the second direction (Y-axis direction), are alternately disposed, and the first bridge bank BNSD1 is disposed between the second emission area EA2 and the third emission area EA3. The first emission areas EA1 and the second emission areas EA2, which are aligned in the first direction (X-axis direction) crossing the folding direction, are disposed alternately, and the second bridge bank BNSD2 is disposed between the first emission area EA1 and the second emission area EA2. The second emission areas EA2 and the third emission areas EA3, which are aligned in the first direction (X-axis direction) crossing the folding direction, are disposed alternately, and the second bridge bank BNSD2 is disposed between the second emission area EA2 and the third emission area EA3. The first bridge bank BNSD1 and the second bridge bank BNSD2 may be disposed between the emission areas EA1, EA2, and EA3 spaced apart from each other, thereby electrically connecting the common electrodes CE1, CE2, and CE3 of the first to third light-emitting elements ED1, ED2, and ED3 to each other. In an embodiment, the first direction (X-axis direction) and the second direction (Y-axis direction) may be perpendicular to each other.

When a bank structure having a metallic material is formed entirely in the folding area FDA, cracks may occur due to stresses such as compressive stress and tensile stress in a folded or stretched state. However, when the second bank structure is formed in a bridge shape to connect the emission areas EA1, EA2, and EA3 to each other, cracks may be prevented.

The first bridge bank BNSD1 mainly extending in the folding direction or the second direction (Y-axis direction) may have a zigzag shape in a plan view. That is, the first bridge bank BNSD1 may extend in a zigzag shape in the folding direction or the second direction (Y-axis direction). As the display device 10 is repeatedly folded, the length of the first bridge bank BNSD1 may increase and decrease in the folding direction or the second direction (Y-axis direction). The first bridge bank BNSD1 may have relatively low stress in folding and may prevent crack occurrence.

In the first direction (X-axis direction) crossing the folding direction, the first bridge bank BNSD1 may have a width w15 that is less than widths w11, w12, w13, and w14 of the first to third emission areas EA1, EA2, and EA3. As the second emission areas EA2 are disposed rotated by 90°, they may have two widths w12 and w14 in the first direction (X-axis direction). In an embodiment, the width w15 of the first bridge bank BNSD1 may be 1 micrometer (μm) to 10 μm. In this range, the common electrodes CE1, CE2, and CE3 may be electrically connected with each other and cracks may not occur even when folded.

The width w15 of the zigzag-shaped first bridge bank BNSD1 may be constant. Without being limited thereto, the widths w15 of the first bridge bank BNSD1 may be different in a portion adjacent to the emission areas EA1, EA2, and EA3 and a portion distant from the emission areas EA1, EA2, and EA3.

The second bridge bank BNSD2 extending in the first direction (X-axis direction) may have a different shape from the first bridge bank BNSD1. In an embodiment, the second bridge bank BNSD2 may have a straight line shape. In the folding direction or the second direction (Y-axis direction), the second bridge bank BNSD2 may have a width w25 that is less than widths w21, w22, w23, and w24 of the first to third emission areas EA1, EA2, and EA3. As the second emission areas EA2 are disposed rotated by 90°, they may have two widths w22 and w24 in the folding direction or the second direction (Y-axis direction). In an embodiment, the width w25 of the second bridge bank BNSD2 may be 1 μm to 10 μm. The width w25 of the second bridge bank BNSD2 may be constant. Without being limited thereto, the width w25 of the second bridge bank BNSD2 may vary along the first direction (X-axis direction).

Referring to FIG. 9A, the second bank structure BNS2 may include the first bank BN1 and the second bank BN2, similarly to the first bank structure BNS1. The above description of the first bank BN1 and the second bank BN2 of the first bank structure BNS1 may be applied to the first bank BN1 and the second bank BN2 of the second bank structure BNS2. The second bank BN2 of the second bank structure BNS2 may have the tip TIP protruding compared to the first bank BN1 and an undercut structure of the first bank BN1 may be formed thereunder.

The common electrodes CE1, CE2, and CE3 of the emission areas EA1, EA2, and EA3, which are spaced apart from each other, may contact the first bank BN1 of the second bank structure BNS2 to be electrically connected thereto. One ends of the common electrodes CE1, CE2, and CE3 may contact the first bank BN1 of the first bridge bank BNSD1, and opposite ends of the common electrodes CE1, CE2, and CE3 may contact the first bank BN1 of the second bridge bank BNSD2.

The first bank BN1 and the second bank BN2 of the second bank structure BNS2 may have the same layout as the second bank structure BNS2 of FIG. 8 in a plan view, but may have different widths from each other. The first bank BN1 may have a width less than that of the second bank BN2. The first bank BN1 of the first bridge bank BNSD1 may have a zigzag shape. The first bank BN1 of the second bridge bank BNSD2 may have a straight line shape. The second bank BN2 of the first bridge bank BNSD1 may have a zigzag shape. The second bank BN2 of the second bridge bank BNSD2 may have a straight line shape.

Referring to FIG. 9B, in the first bridge bank BNSD1, a width w151 of the first bank BN1 may be less than a width w152 of the second bank BN2 in the first direction (X-axis direction). The width w152 of the second bank BN2 in the first direction (X-axis direction) may be the same as the width w15 of the first bridge bank BNSD1. Referring to FIG. 9C, in the second bridge bank BNSD2, a width w251 of the first bank BN1 may be less than a width w252 of the second bank BN2 in the second direction (Y-axis direction). The width w252 of the second bank BN2 in the second direction (Y-axis direction) may be the same as the width w25 of the second bridge bank BNSD2.

In the folding area FDA, the lower inorganic encapsulation layer TFE1 (TL1, TL2 and TL3) may be disposed above the pixel defining layer PDL in the area where the second bank structure BNS2 is not disposed. In the vicinity of the emission areas EA1, EA2, and EA3, the light-emitting layers EL1, EL2, and EL3 and the common electrodes CE1, CE2, and CE3 may be disposed between the lower inorganic encapsulation layer TL1, TL2, or TL3 and the pixel defining layer PDL.

The first to third inorganic layers TL1, TL2, and TL3 of the lower inorganic encapsulation layer TFE1 may be spaced apart from each other in the folding area FDA. The first to third inorganic layers TL1, TL2, and TL3 may seal one ends of the light-emitting layers EL1, EL2, and EL3 and the common electrodes CE1, CE2, and CE3. In an embodiment, the pixel defining layer PDL may contact the lower inorganic encapsulation layers TL1, TL2, and TL3 and the organic encapsulation layer TFE2. In an embodiment, the pixel defining layer PDL may contact the lower inorganic encapsulation layers TL1, TL2, and TL3 and the reinforcement layer.

Since the configuration described with reference to FIG. 6, except for the second bank structure BNS2, may be applied in the same way, the corresponding description will be omitted.

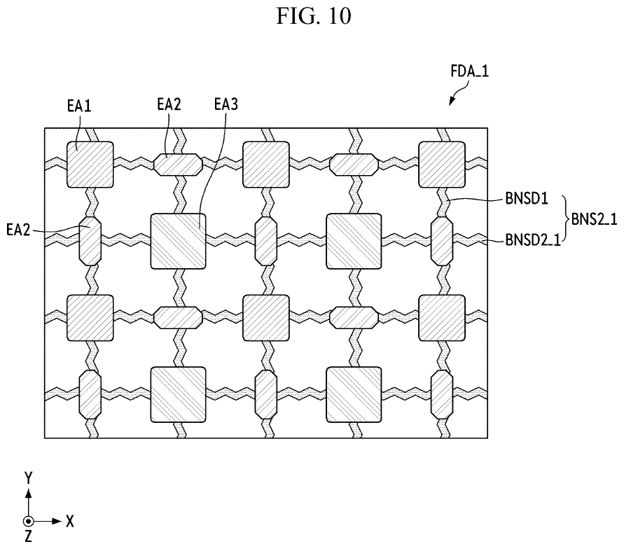

FIG. 10 is a plan view showing an embodiment of the arrangement of the emission areas EA1, EA2, and EA3 and a second bank structure BNS2_1 in a folding area FDA_1 of the display device 10.

FIG. 10 is different from FIG. 8 in that the second bridge bank BNSD2_1 mainly extending in the first direction (X-axis direction) has a zigzag shape. When zigzag-shaped bridge banks are disposed not only in the second direction (Y-axis direction) but also in the first direction (X-axis direction), the display device 10 may be folded in the first direction (X-axis direction) as well.

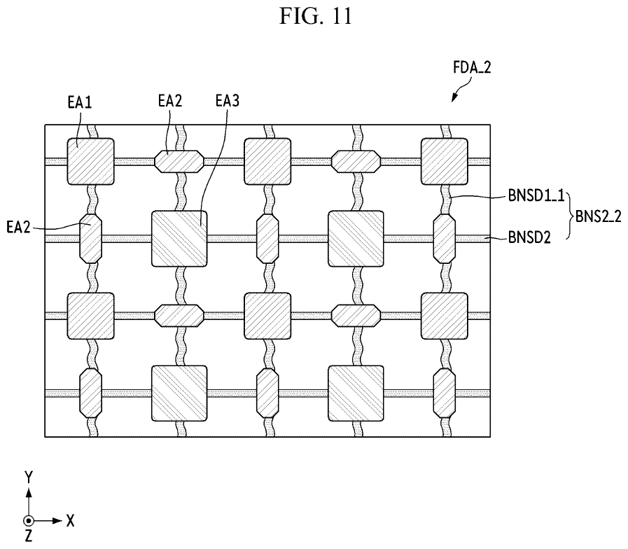

FIG. 11 is a plan view showing an embodiment of the arrangement of the emission areas EA1, EA2, and EA3 and a second bank structure BNS2_2 in a folding area FDA_2 of the display device 10.

FIG. 11 is different from FIG. 8 in that a first bridge bank BNSD1_1 mainly extending in the folding direction or the second direction (Y-axis direction) has a wave shape. The wave-shaped first bridge bank BNSD1_1 may increase and decrease in length in the folding direction or the second direction (Y-axis direction) while having relatively low stress in folding. The wave shape may at least partially include a curved portion while the zigzag shape may consist of straight lines.

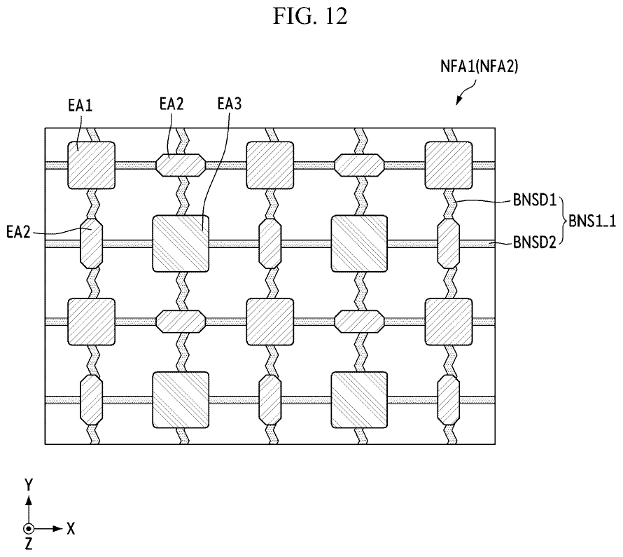

FIG. 12 is a plan view showing an embodiment of the arrangement of the emission areas EA1, EA2, and EA3 and a first bank structure BNS1_1 in the non-folding areas NFA1 and NFA2 of the display device 10.

FIG. 12 is different from FIG. 5 in that, similarly to the second bank structure BNS2 of the folding area FDA, the first bank structure BNS1_1 may include the first bridge bank BNSD1 and the second bridge bank BNSD2, rather than being formed entirely in the non-folding areas NFA1 and NFA2 excluding the emission areas EA1, EA2, and EA3. The above description of the first bridge bank BNSD1 and the second bridge bank BNSD2 of the second bank structure BNS2_1 may be applied to the first bridge bank BNSD1 and the second bridge bank BNSD2 of the first bank structure BNS1_1. When the non-folding areas NFA1 and NFA2 include bridge banks, the display device 10 may be stretched in the non-folding areas NFA1 and NFA2.

The display device according to one embodiment of the present disclosure can be applied to various electronic devices. The electronic device according to the one embodiment of the present disclosure includes the display device described above, and may further include modules or devices having additional functions in addition to the display device.

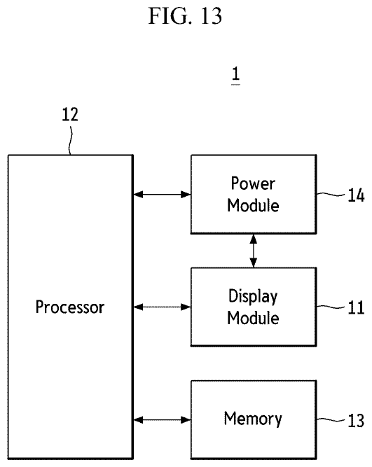

FIG. 13 is a block diagram of an electronic device according to one embodiment of the present disclosure.

Referring to FIG. 13, the electronic device 1 according to one embodiment of the present disclosure may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 15 may store data information necessary for the operation of the processor 12 or the display module 11. When the processor 12 executes an application stored in the memory 15, an image data signal and/or an input control signal is transmitted to the display module 11, and the display module 11 can process the received signal and output image information through a display screen.

The power module 14 may include a power supply module such as, for example a power adapter or a battery, and a power conversion module that converts the power supplied by the power supply module to generate power necessary for the operation of the electronic device 1.

At least one of the components of the electronic device 11 according to the one embodiment of the present disclosure may be included in the display device 10 according to the embodiments of the present disclosure. In addition, some modules of the individual modules functionally included in one module may be included in the display device 10, and other modules may be provided separately from the display device 10. For example, the display device 10 may include the display module 11, and the processor 12, the memory 13, and the power module 14 may be provided in the form of other devices within the electronic device 11 other than the display device 10.

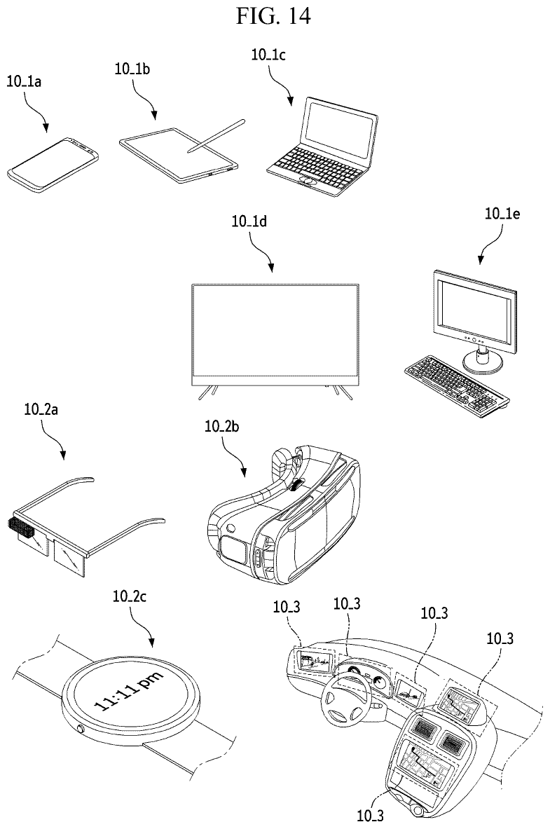

FIG. 14 is a schematic diagram of an electronic device according to various embodiments of the present disclosure.

Referring to FIG. 14, various electronic devices to which display devices 10 according to embodiments of the present disclosure are applied may include not only image display electronic devices such as a smart phone 10_1a, a tablet PC (personal computer) 10_1b, a laptop 10_1c, a TV 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as a CID (Center Information Display) and a room mirror display arranged on a dashboard, center fascia, and dashboard of an automobile.

Embodiments of the disclosure should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate in which a first emission area, a second emission area, and a third emission area spaced apart from each other are defined;
a first bridge bank comprising:
a first bank on the substrate and a second bank on the first bank, between the first emission area and the second emission area; and
a second bridge bank comprising:
a first bank on the substrate and a second bank on the first bank, between the second emission area and the third emission area,
wherein the first emission area and the second emission area are aligned in a first direction,
the first bridge bank mainly extends in the first direction, and has a zigzag shape or a wave shape,
the second emission area and the third emission area are aligned in a second direction crossing the first direction,
the second bridge bank extends in the second direction,
a width of the first bank of the first bridge bank is less than a width of the second bank of the first bridge bank, and
a width of the first bank of the second bridge bank is less than a width of the second bank of the second bridge bank.

2. The display device of claim 1, wherein in the second direction, a width of the first bridge bank is less than a width of the first emission area and a width of the second emission area.

3. The display device of claim 2, wherein the width of the first bridge bank is 1 micrometer to 10 micrometers.

4. The display device of claim 1, wherein in the first direction, a width of the second bridge bank is less than a width of the second emission area and a width of the third emission area.

5. The display device of claim 4, wherein the width of the second bridge bank is 1 micrometer to 10 micrometers.

6. The display device of claim 1, wherein the second bridge bank has a straight line shape extending in the second direction.

7. The display device of claim 1, wherein the second bridge bank mainly extends in the second direction, and has a zigzag shape or a wave shape.

8. The display device of claim 1, wherein the display device is folded in the first direction.

9. The display device of claim 1, further comprising:
a first pixel electrode on the substrate in the first emission area;
a second pixel electrode on the substrate in the second emission area;
a pixel defining layer defining the first emission area and the second emission area on the substrate;
a first light-emitting layer on the first pixel electrode and a first common electrode on the first light-emitting layer; and
a second light-emitting layer on the second pixel electrode and a second common electrode on the second light-emitting layer,
wherein the first common electrode and the second common electrode are spaced apart from each other.

10. The display device of claim 9, wherein the first bank of the first bridge bank contacts one end of the first common electrode and one end of the second common electrode.

11. The display device of claim 9, further comprising a first inorganic layer on the first common electrode and the first bridge bank.

12. The display device of claim 11, wherein the first inorganic layer is spaced apart from a top surface of the second bank of the first bridge bank.

13. The display device of claim 12, wherein the first inorganic layer contacts the pixel defining layer.

14. The display device of claim 11, further comprising a second inorganic layer on the second common electrode and the first bridge bank,
wherein the first inorganic layer and the second inorganic layer are spaced apart from each other.

15. The display device of claim 9, further comprising a residual pattern disposed between the first pixel electrode and the pixel defining layer.

16. A display device comprising:
a substrate in which a plurality of emission areas is defined;
a first bridge bank extending in a first direction, and comprising:
a first bank on the substrate and a second bank on the first bank; and
a second bridge bank extending in a second direction crossing the first direction, and comprising:
a first bank on the substrate and a second bank on the first bank,
wherein the plurality of emission areas is aligned in the first direction and the second direction,
the first bridge bank is disposed between emission areas next to each other and aligned in the first direction among the plurality of plurality of emission areas,
the second bridge bank is disposed between emission areas next to each other and aligned in the second direction among the plurality of plurality of emission areas,
a width of the first bank of the first bridge bank is less than a width of the second bank of the first bridge bank, and
a width of the first bank of the second bridge bank is less than a width of the second bank of the second bridge bank.

17. The display device of claim 16, wherein a shape of the first bridge bank extending in the first direction and a shape of the second bridge bank extending in the second direction are different from each other.

18. The display device of claim 17, wherein the first bridge bank manly extending in the first direction has a zigzag shape or a wave shape, and
the second bridge bank extending in the second direction has a straight line shape.

19. The display device of claim 16, wherein each of the plurality of emission areas is disposed at a grid point of grid patterns which intersect in the first direction and the second direction.

20. A display device comprising:
a substrate in which a first emission area, a second emission area, a third emission area, and a fourth emission area spaced apart from each other are defined;
a first bridge bank mainly extending in a first direction, and comprising:
a first bank on the substrate and a second bank on the first bank; and
a second bridge bank extending in a second direction crossing the first direction, and comprising:
a first bank on the substrate and a second bank on the first bank,
wherein the first emission area is aligned with the second emission area in the first direction, and is aligned with the fourth emission area in the second direction,
the third emission area is aligned with the fourth emission area in the first direction, and is aligned with the second emission area in the second direction,
the first bridge bank has a zigzag shape or wave shape,
the second bridge bank has a straight line shape,
a width of the first bank of the first bridge bank is less than a width of the second bank of the first bridge bank, and
a width of the first bank of the second bridge bank is less than a width of the second bank of the second bridge bank.

21. A foldable display device comprising:
a display panel in which a folding area and a non-folding area disposed around the folding area are defined, the display panel comprising:
a substrate comprising:
a first emission area, a second emission area, and a third emission area spaced apart from each other in the folding area;
a first bridge bank comprising:
a first bank on the substrate and a second bank on the first bank, between the first emission area and the second emission area; and
a second bridge bank comprising:
a first bank on the substrate and a second bank on the first bank, between the second emission area and the third emission area,
wherein the first emission area and the second emission area are aligned in a first direction,
the first bridge bank mainly extends in the first direction, and has a zigzag shape or wave shape,
the second emission area and the third emission area are aligned in a second direction crossing the first direction,
the second bridge bank extends in the second direction,
a width of the first bank of the first bridge bank is less than a width of the second bank of the first bridge bank, and
a width of the first bank of the second bridge bank is less than a width of the second bank of the second bridge bank.
